(19) United States
(12) Patent Application Publication
(10) Pub. No.: US 2011/0069465 A1
(43) Pub. Date: Mar. 24, 2011

(54) PRINTED CIRCUIT BOARD ASSEMBLY

(75) Inventor: Ming-Chih HSIEH, Tu-Cheng (TW)

(73) Assignee: HON HAI PRECISION INDUSTRY CO., LTD., Tu-Cheng (TW)

(21) Appl. No.: 12/579,423

(22) Filed: Oct. 15, 2009

(30) Foreign Application Priority Data
Sep. 24, 2009 (CN) 200910307649.7

(51) Int. Cl. H05K 1/11

(52) U.S. Cl. 361/803

(57) ABSTRACT

A printed circuit board (PCB) assembly includes two function boards which can be separated from each other. The PCB assembly can satisfy electronic devices of different dimensions, by arranging the separated function boards in appropriate available space in the electronic devices.

### BACKGROUND

1. Technical Field

The present disclosure relates to printed circuit boards (PCBs) and, particularly, to a PCB assembly accommodating electronic devices of different dimensions.

2. Description of Related Art

Many electronic devices include PCBs for hosting various electronic elements. A PCB of an electronic device may be an integrated single board, shaped to conform to the physical design of the electronic device. However, when dimensions of the electronic device changes, such as decreased size, the PCB no longer corresponds in size to the electronic device. A new PCB must be manufactured to match the new configuration of the electronic device, which can increase costs and is inconvenient.

### BRIEF DESCRIPTION OF THE DRAWINGS

FIG. 1 is a top plan view of an exemplary embodiment of a printed circuit board (PCB) assembly.

FIG. 2 is a front side plan view of the PCB assembly of FIG. 1, connected to a signal cable in a first arrangement.

FIG. 3 is a front side plan view of the PCB assembly of FIG. 1, connected to a signal cable in a second arrangement.

FIG. 4 is a front side plan view of the PCB assembly of FIG. 1, connected to a signal cable in a third arrangement.

### DETAILED DESCRIPTION

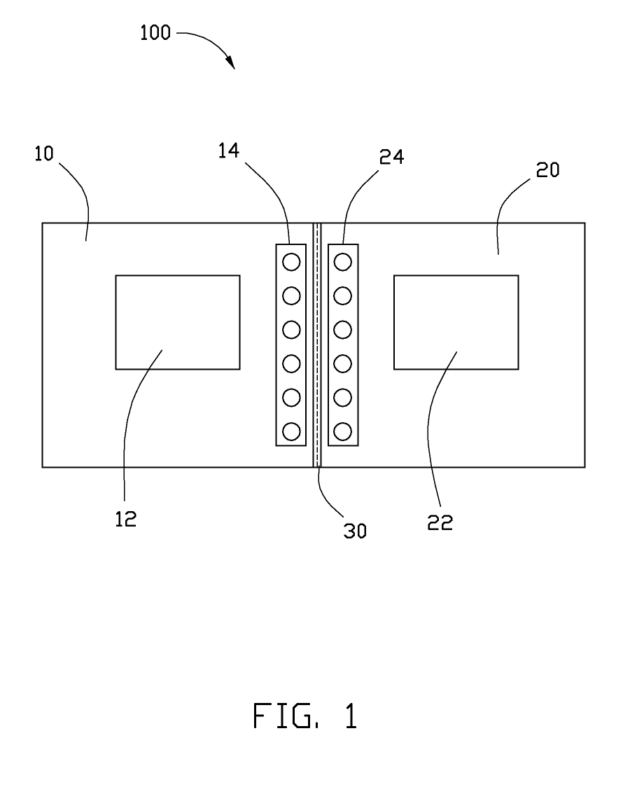

Referring to FIG. 1, an exemplary embodiment of a printed circuit board (PCB) assembly 100 is used in electronic devices. The PCB assembly 100 can satisfy electronic devices of different dimensions.

The PCB assembly 100 includes two integral function boards 10 and 20 separated by a V-shaped groove 30, effectively providing two individual function boards.

In other embodiments, the PCB assembly 100 may include more than two function boards separated by V-shaped grooves. Alternatively, the separating groove can have other shapes.

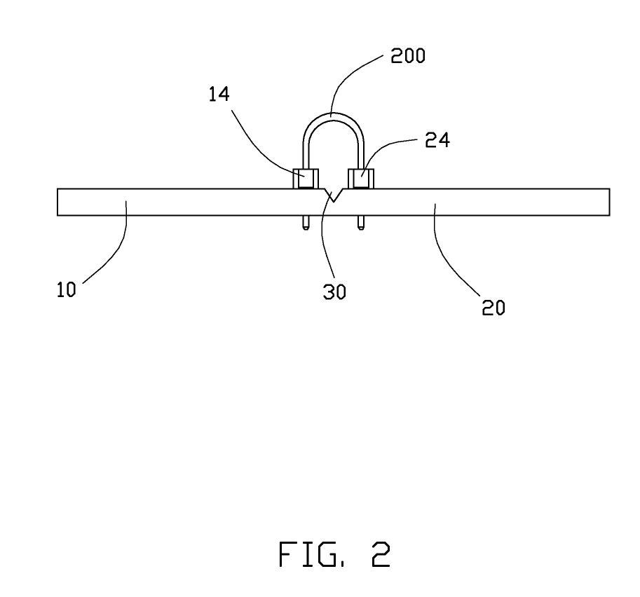

The function board 10 includes a function module 12, and function board 20 includes a function module 22. The function modules 12 and 22 can include requisite electrical elements corresponding to function. A signal connector 14 is mounted on the function board 10 adjacent to the groove 30, electrically connecting to the function module 12. A signal connector 24 is mounted on the function board 20 and adjacent to the groove 30, electrically connected to the function module 22. The two function modules 12 and 22 can communicate with each other via a signal cable 200 (shown in FIG. 2) between the signal connector 14 and the signal connector 24.

Referring to FIG. 2, if the electronic device dimensions can accommodate the entire PCB assembly 100, including function boards 10 and 20 connected to and coplanar with each other, the signal cable 200 is connected between the signal connector 14 and the signal connector 24, and the PCB assembly 100 is positioned appropriately in the electronic device.

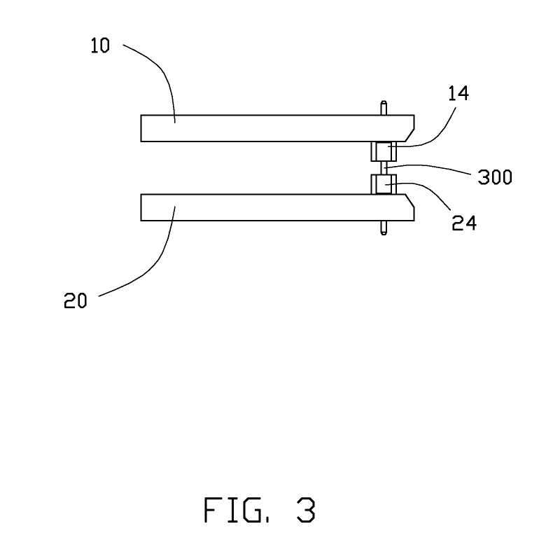

Referring to FIG. 3, however, if dimensions of the electronic device cannot accommodate the entire PCB assembly 100 with the function boards 10 and 20 connected to and coplanar with each other each other, the PCB assembly 100 is separated into two individual function boards 10 and 20 along the groove 30. The two individual function boards 10 and 20 overlap as required by available space. The signal cable 300 is connected between the signal connector 14 and the signal connector 24.

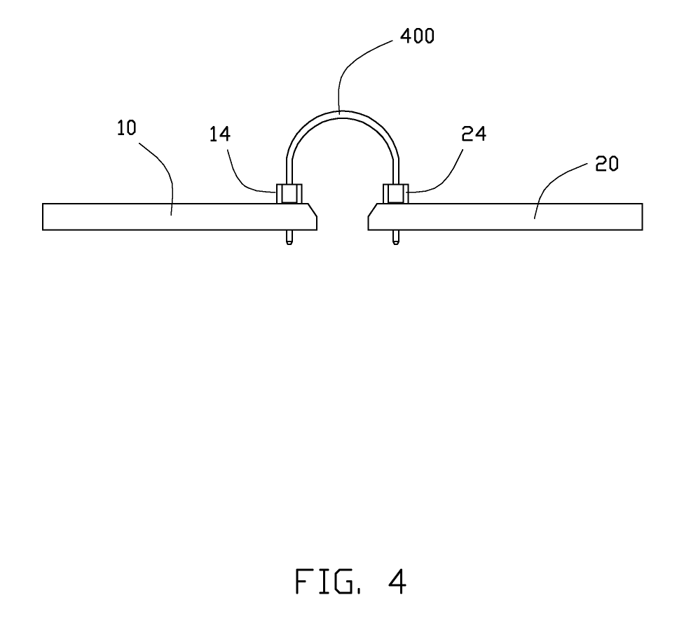

Referring to FIG. 4, if dimensions of the electronic device can accommodate the entire PCB assembly 100 with the function boards 10 and 20 connected to and coplanar with each other, but some elements of the electronic device infringe on certain areas, interfering with the PCB assembly 100, the PCB assembly 100 can be separated into its two individual function boards 10 and 20, which may then be relocated as required to an appropriate location, whereby the elements are accommodated therebetween. The signal cable 400 is connected between the signal connector 14 and the signal connector 24.

The PCB assembly 100 accommodates electronic devices of different dimensions via separating the PCB assembly 100 into two individual function boards 10 and 20, and then arranging the two individual function boards 10 and 20 in appropriate places of the electronic devices, which is very convenient and can save costs.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board (PCB) assembly comprising:
at least two function boards, each comprising a function module, each two function boards segregated by a groove defined therebetween, by means of which the at least two function boards can be physically separated; and
at least two signal connectors corresponding to the at least two function boards, wherein each of the at least two signal connectors is mounted on a corresponding function board and electrically connected to the function module of the corresponding function board, the function boards are operable to communicate with each other via a signal cable connected between the signal connectors of the two function boards.

2. The PCB assembly of claim 1, wherein the groove is V-shaped.
